(19) United States
(12) Patent Application Publication
(10) Pub. No.: US 2016/0254791 A1
(43) Pub. Date: Sep. 1, 2016

(54) HIGH FREQUENCY SEMICONDUCTOR INTEGRATED CIRCUIT

(71) Applicant: Kabushiki Kaisha Toshiba, Tokyo (JP)

(72) Inventor: Koji Uejima, Yamato Kanagawa (JP)

(21) Appl. No.: 14/797,876

(22) Filed: Jul. 13, 2015

(30) Foreign Application Priority Data
Feb. 26, 2015 (JP) 2015-036619

(51) Int. Cl. H03F 3/193; H03F 1/02; H03K 17/687; H03F 3/213; H03F 1/56

(52) U.S. Cl. CPC H03F 3/193; H03F 3/213; H03F 1/565; H03K 17/687; H03F 1/0211; H03F 2200/451; H03F 2200/222

(57) ABSTRACT

According to one embodiment, one end of a first line is connected to a first terminal. A first resonance circuit has one end connected to the other end of the first line. A first transistor has one end connected to the other end of a second line, the other end connected to a second terminal, and a control terminal to receive a first control signal. A second transistor has one end connected to the second terminal, and a control terminal to receive a second control signal. A third line is connected to the other end of the second transistor. A second resonance circuit has one end connected to the other end of the third line. A fourth line has one end connected to the other end of the third line, and the other end connected to a third terminal.

### CROSS REFERENCE TO RELATED APPLICATION

This application is based upon and claims the benefit of priority from the prior Japanese Patent Application No. 2015-036619, filed on Feb. 26, 2015, the entire contents of which are incorporated herein by reference.

### FIELD

Embodiments described herein relate to a high frequency semiconductor integrated circuit.

### BACKGROUND

High frequency semiconductor integrated circuits, inclusive of high frequency power amplifiers and high frequency switch circuits, are essential components for radio communications systems in the field of mobile communications and the LAN, and are widely used in cellular phones, wireless infrastructure facilities, satellite communications facilities, cable television facilities, and the like.

An increase in leakage of the second, third or n-th order harmonic signals of high frequency signals in a high frequency power amplifier causes malfunction of the semiconductor integrated circuit and the equipment. A problem with a high frequency switch circuit is that an increase in leakage signal due to the generation of the second, third and n-th order harmonics of high frequency signals makes the passage and/or isolation characteristics of the signals deteriorate.

Against the background of the above problems, large reduction in the leakage signal is required for high frequency semiconductor integrated circuits.

### BRIEF DESCRIPTION OF THE DRAWINGS

FIG. 1 is a circuit diagram showing a high frequency switch circuit, as a high frequency semiconductor integrated circuit of a first embodiment;

FIG. 2 is a circuit diagram showing a high frequency switch circuit of a comparative sample to be compared with the first embodiment;

FIG. 3 is a representative circuit schematic of the high frequency switch circuit of the first embodiment when a high frequency signal is outputted to an antenna terminal via a transmission terminal;

FIG. 4 is a representative circuit schematic of the high frequency switch circuit of the comparative sample to be compared with the first embodiment when a high frequency signal is outputted to an antenna terminal via a transmission terminal;

FIG. 5 is a representative circuit schematic of the high frequency switch circuit of the first embodiment when a high frequency signal is outputted to a receiver terminal via the antenna terminal;

FIG. 6 is a representative circuit schematic of the high frequency switch circuit of the comparative sample to be compared with the first embodiment when a high frequency signal is outputted to a receiver terminal via the antenna terminal;

FIG. 7 is a Smith chart of the high frequency switch circuit of the first embodiment;

FIG. 8 includes diagrams showing leakage powers in the high frequency switch circuit of the first embodiment, FIG. 8A is a diagram showing leakage powers while the second harmonic is generated, and FIG. 8B is a diagram showing leakage powers while the third harmonic is generated;

FIG. 9 is a circuit diagram showing a high frequency switch circuit of a second embodiment;

FIG. 10 is a circuit diagram showing a high frequency power amplifier circuit of a third embodiment;

FIG. 11 is a representative circuit schematic of the high frequency power amplifier circuit of the third embodiment;

FIG. 12 is a circuit diagram showing a high frequency power amplifier circuit of a comparative sample to be compared with the third embodiment;

FIG. 13 is a Smith chart of the high frequency power amplifier circuit of the third embodiment;

FIG. 14 includes diagrams showing leakage powers in the high frequency power amplifier circuit of the third embodiment, FIG. 14A is a diagram showing leakage powers while the second harmonic is generated, and FIG. 14B is a diagram showing leakage powers while the third harmonic is generated; and

FIG. 15 is a circuit diagram showing a high frequency switch circuit, as a high frequency semiconductor integrated circuit of a fourth embodiment.

### DETAILED DESCRIPTION

According to one embodiment, a high frequency semiconductor integrated circuit includes a first line, a first resonance circuit, a second line, a first transistor, a second transistor, a third line, a second resonance circuit and a fourth line. One end of the first line is connected to a first terminal. A length of the first line is equal to [n+( 1/12)] times a wavelength of a first high frequency signal when the first high frequency signal is transmitted through the first line, where n is zero, or an integer equal to or greater than one. One end of the first resonance circuit is connected to the other end of the first line. The other end of the first resonance circuit is connected to a ground potential. One end of the second line is connected to the other end of the first line. A length of the second line is equal to [n+(⅙)] times the wavelength of the first high frequency signal when the first high frequency signal is transmitted through the second line. One end of a first transistor is connected to the other end of the second line. The other end of the first transistor is connected to a second terminal. A control terminal of the first transistor receives a first control signal. One end of a second transistor is connected to the second terminal. A control terminal of the second transistor receives a second control signal. One end of the third line is connected to the other end of the second transistor. A length of the third line is equal to [n+(⅙)] times a wavelength of a second high frequency signal when the second high frequency signal is transmitted through the third line. One end of the second resonance circuit is connected to the other end of the third line. The other end of the second resonance circuit is connected to the ground potential. One end of the fourth line is connected to the other end of the third line. The other end of the fourth line is connected to a third terminal. A length of the fourth line is equal to [n+( 1/12)] times the wavelength of the second high frequency signal when the second high frequency signal is transmitted through the fourth line.

Multiple other embodiments will be hereinbelow described with reference to the drawings. Throughout the drawings, the same reference signs denote the same or similar portions.

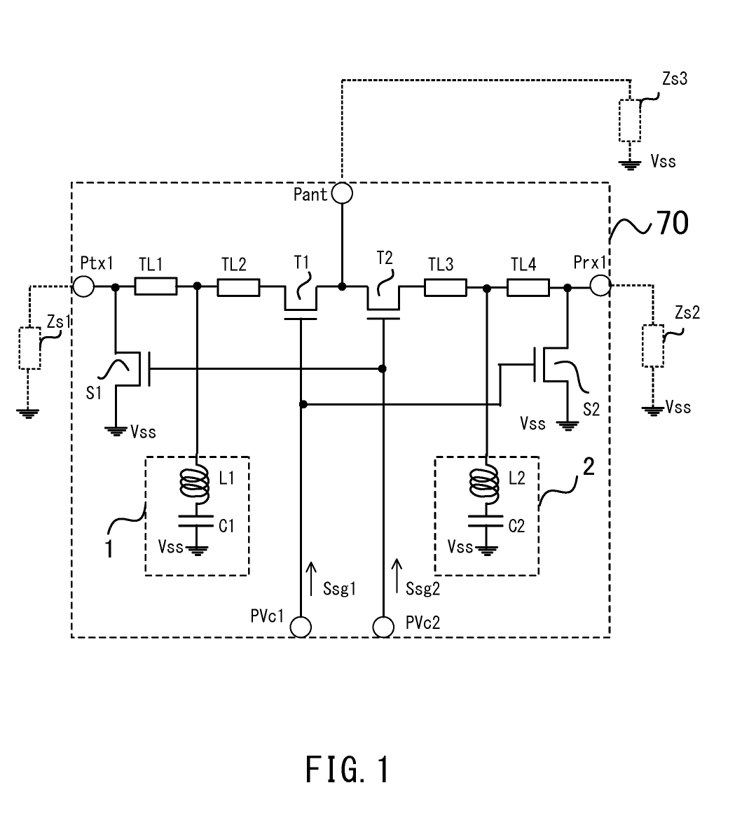

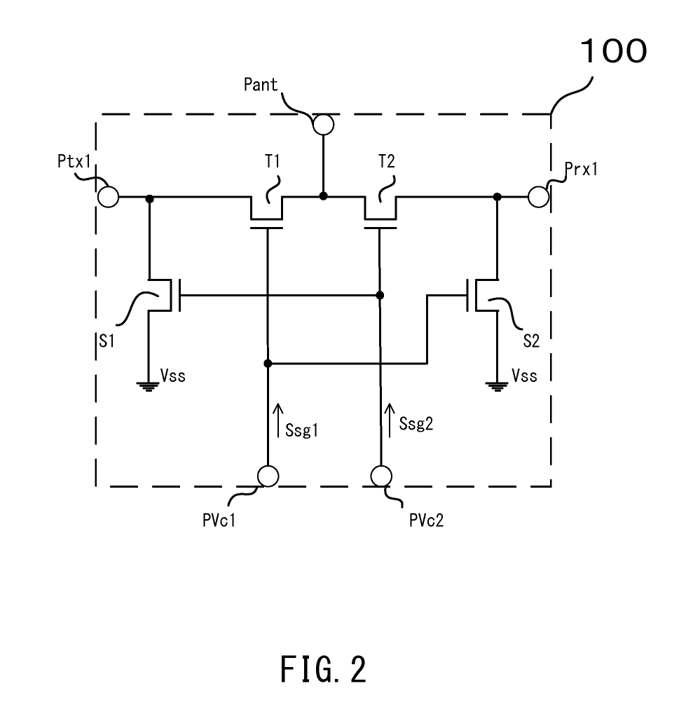

A high frequency switch circuit, as the high frequency semiconductor integrated circuit of the first embodiment, will be described with reference to FIGS. 1 and 2. FIG. 1 is a circuit diagram showing the high frequency switch circuit. FIG. 2 is a circuit diagram showing a high frequency switch circuit of a comparative sample.

The embodiment reduces leakage signal to a large extend by: providing the first transmission line and the second transmission line between the transmission terminal and the first through transistor; providing the third transmission line and the fourth transmission line between the second through transistor and the receiver terminal; providing the first resonance circuit between the ground potential and the connection point between the first transmission line and the second transmission line; and providing the second resonance circuit between the ground potential and the connection point between the third transmission line and the fourth transmission line.

As shown in FIG. 1, a high frequency switch circuit 70, as the high frequency semiconductor integrated circuit, includes a resonance circuit 1, a resonance circuit 2, a shunt transistor S1, a shunt transistor S2, a through transistor T1, a through transistor T2, a transmission line TL1, a transmission line TL2, a transmission line TL3, a transmission line TL4, a terminal Pant, a terminal Prx1, a terminal Ptx1, a terminal PVc1 and a terminal PVc2.

The high frequency switch circuit 70 is a SPDT (Single Pole Double Throw) switch. The high frequency switch circuit 70 is widely used in cellular phones, wireless infrastructure facilities, satellite communications facilities, cable television facilities, and the like.

A control signal Ssg1 (first control signal) is inputted via the terminal PVc1, and a control signal Ssg2 (second control signal) is inputted via the terminal PVc2.

One end of the transmission line TL1 (first line) is connected to the terminal Ptx1 (first terminal). The transmission line TL1 (first line) is set such that once a first high frequency signal to be transmitted (a signal to be transmitted from the terminal Ptx1 to the terminal Pant) is inputted into the transmission line TL1, a line length of the transmission line TL1 becomes equal to one twelfth of the wavelength (λ) of the first high frequency signal.

One end of the transmission line TL2 (second line) is connected to the other end of the transmission line TL1. The transmission line TL2 (second line) is set such that once the first high frequency signal to be transmitted is inputted into the transmission line TL2, a line length of the transmission line TL2 becomes equal to one sixth of the wavelength (λ) of the first high frequency signal.

One end of the shunt transistor S1 (third transistor) is connected to the terminal Ptx1, and the other end of the shunt transistor S1 is connected to a ground potential Vss. The control signal Ssg2 is inputted into the gate (control terminal) of the shunt transistor S1. One end of the through transistor T1 (first transistor) is connected to the other end of the transmission line TL2, and the other end of the through transistor T1 is connected to the terminal Pant (second terminal). The control signal Ssg1 (first control signal) is inputted into the gate (control terminal) of the through transistor T1.

One end of the resonance circuit 1 (first resonance circuit) is connected to the other end of the transmission line TL1, and the other end of the resonance circuit 1 is connected to the ground potential Vss. The resonance circuit 1 is formed from an inductor L1 and a capacitor C1 connected together in series. Characteristic impedance of the resonance circuit 1 at a frequency equal to or less than that of the second harmonic of the first high frequency signal is set to almost infinity. Characteristic impedance of the resonance circuit 1 at a frequency of the third harmonic of the first high frequency signal is set at almost zero.

In the case shown in FIG. 1, the inductor L1 is provided on the side of the other end of the transmission line TL1, while the capacitor C1 is provided on the side of the ground potential Vss. However, the inductor L1 and the capacitor C1 may be reversely provided such that: the capacitor C1 is provided on the side of the other end of the transmission line TL1; and the inductor L1 is provided on the side of the ground potential Vss.

One end of the through transistor T2 (second transistor) is connected to the terminal Pant. The control signal Ssg2 (second control signal) is inputted into the gate (control terminal) of the through transistor T2.

One end of the transmission line TL3 (third line) is connected to the other end of the through transistor T2. The transmission line TL3 (third line) is set such that once a second high frequency signal to be transmitted (a signal to be transmitted from the terminal Pant to the terminal Prx1) is inputted into the transmission line TL3, a line length of the transmission line TL3 becomes equal to one sixth of the wavelength (λ) of the second high frequency signal.

One end of the transmission line TL4 (fourth line) is connected to the other end of the transmission line TL3. The transmission line TL4 (fourth line) is set such that once the second high frequency signal to be transmitted is inputted into the transmission line TL4, a line length of the transmission line TL4 becomes equal to one twelfth of the wavelength (λ) of the second high frequency signal.

One end of the shunt transistor S2 (fourth transistor) is connected to the other end of the transmission line TL4 and the terminal Prx1. The other end of the shunt transistor S2 is connected to the ground potential Vss. The control signal Ssg1 is inputted into the gate (control terminal) of the shunt transistor S2.

One end of the resonance circuit 2 (second resonance circuit) is connected to the other end of the transmission line TL3, and the other end of the resonance circuit 2 is connected to the ground potential Vss. The resonance circuit 2 is formed from an inductor L2 and a capacitor C2 connected together in series. Characteristic impedance of the resonance circuit 2 at a frequency equal to or less than that of the second harmonic of the second high frequency signal is set to almost infinity. Characteristic impedance of the resonance circuit 2 at a frequency of the third harmonic of the second high frequency signal is set at almost zero.

In the case shown in FIG. 1, the inductor L2 is provided on the side of the other end of the transmission line TL3, while the capacitor C2 is provided on the side of the ground potential Vss. However, the inductor L2 and the capacitor C2 may be reversely provided such that: the capacitor C2 is provided on the side of the other end of the transmission line TL3; and the inductor L2 is provided on the side of the ground potential Vss.

When the control signal Ssg1 is in an enable state (at a high level, for example) and the control signal Ssg2 is in a disable state (at a low level, for example), the high frequency switch circuit 70 outputs the first high frequency signal to the terminal Pant as an antenna terminal via the terminal Ptx1 as the transmission terminal.

When the control signal Ssg1 is in the disable state (at the low level, for example) and the control signal Ssg2 is in the enable state (at the high level, for example), the high frequency switch circuit 70 outputs the second high frequency signal to the terminal Prx1 as the receiver terminal via the terminal Pant as the antenna terminal. The SPDT switch uses the same frequency for the first high frequency signal and the second high frequency signal.

Outside the high frequency switch circuit 70, a terminal impedance Zs1 is provided between the terminal Ptx1 and the ground potential Vss (on the side of the terminal Ptx1); a terminal impedance Zs3 is provided between the terminal Pant and the ground potential Vss (on the side of the terminal Pant); and a terminal impedance Zs2 is provided between the terminal Prx1 and the ground potential Vss (on the side of the terminal Prx1).

In this respect, each of the terminal impedances is impedance set in accordance with the frequency of the high frequency signal at which the high frequency switch circuit 70 works, and is set at 50Ω (at 25Ω, 75Ω or the like, depending on cases), for example.

A SOI (Silicon On Insulator)-type N-channel MOSFET (Metal Oxide Semiconductor Field Effect Transistor) is used for the shunt transistor S1, the shunt transistor S2, the through transistor T1 and the through transistor T2. A microstrip line, a coplanar strip line or the like is used for the transmission line TL1, the transmission line TL2, the transmission line TL3 and the transmission line TL1.

Characteristic impedance of the transmission line TL1 and the transmission line TL2 is set at the same value as the terminal impedance Zs1 is. Characteristic impedance of the transmission line TL3 and the transmission line TL4 is set at the same value as the terminal impedance Zs2 is.

In this respect, the characteristic impedance is impedance of the corresponding transmission line which is set in accordance with the frequency of the high frequency signal at which the high frequency switch circuit 70 works.

As shown in FIG. 2, a high frequency switch circuit 100 of the comparative sample is provided with the shunt transistor S1, the shunt transistor S2, the through transistor T1, the through transistor T2, the terminal Pant, the terminal Prx1, the terminal Ptx1, the terminal PVc1 and the terminal PVc2.

The high frequency switch circuit 100 of the comparative sample lacks the transmission lines TL1 to TL4, the resonance circuit 1 and the resonance circuit 2 which are included in the high frequency switch circuit 100. For this reason, descriptions for the configuration of the high frequency switch circuit 100 are omitted.

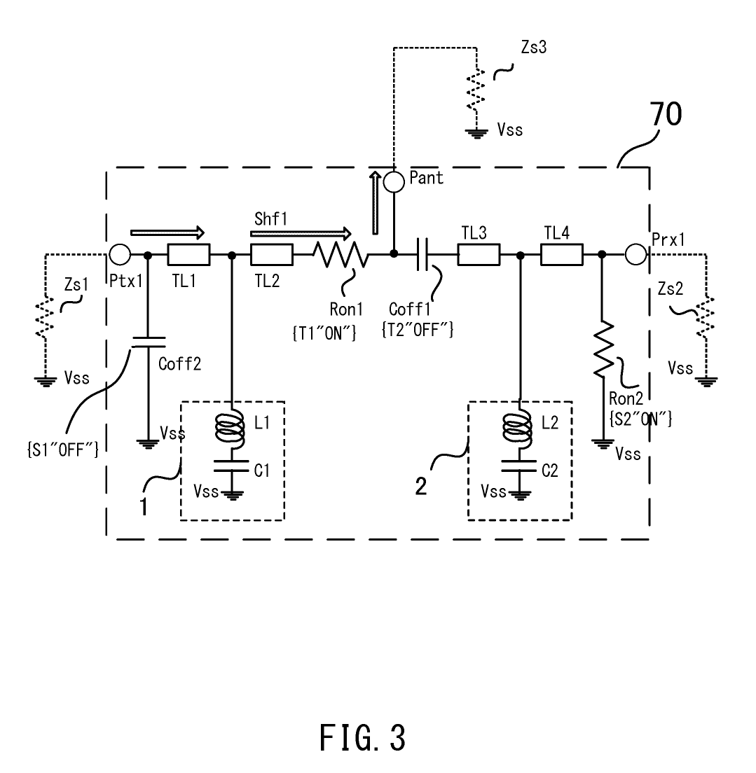

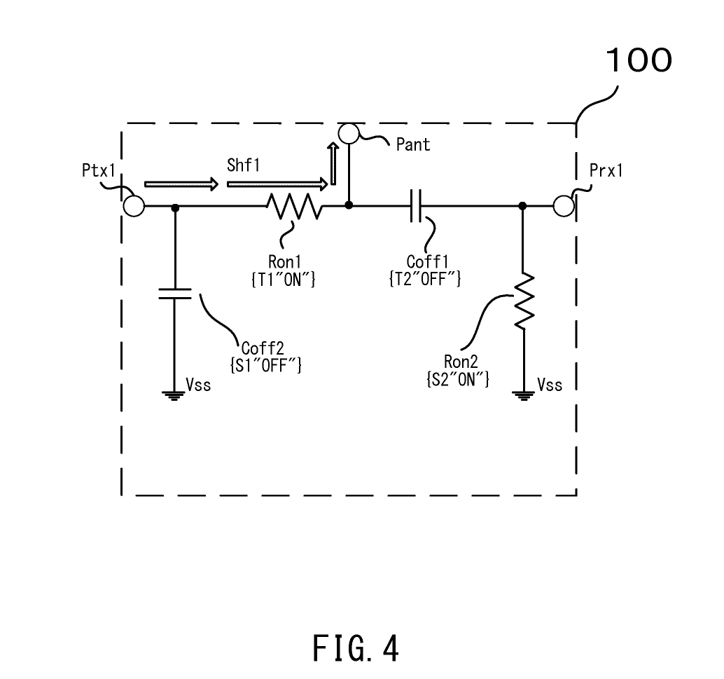

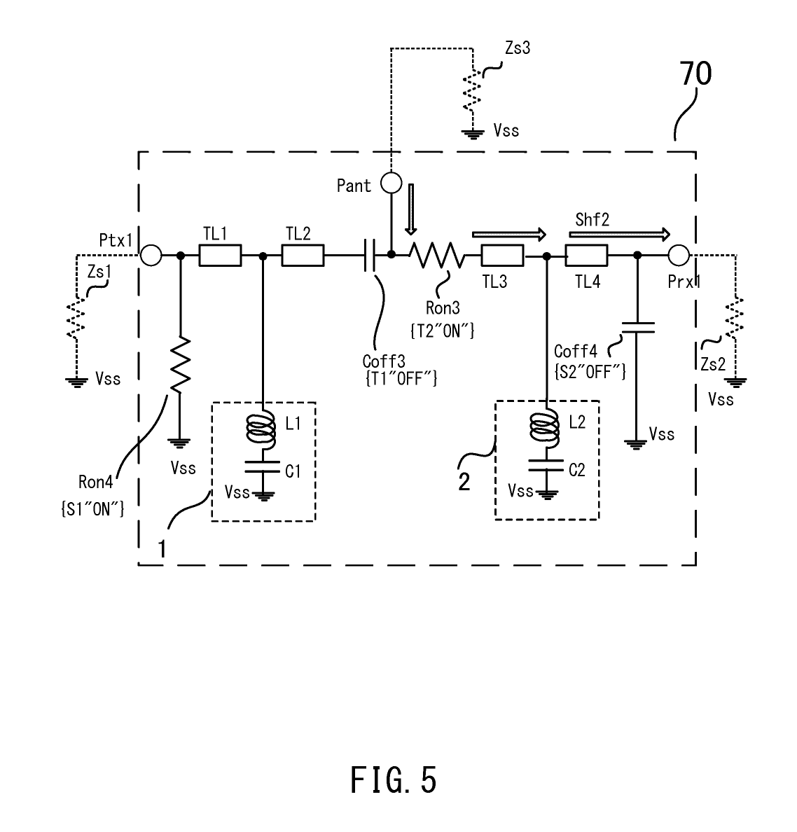

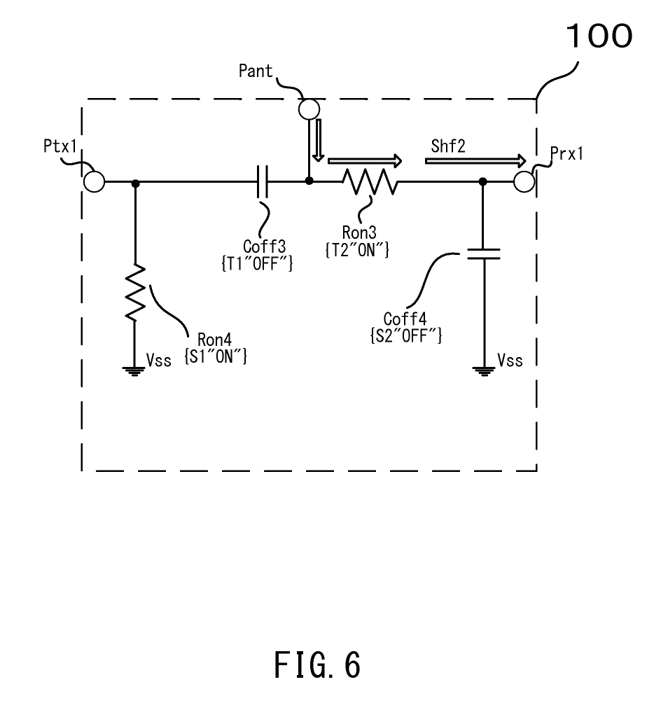

How the high frequency switch circuit works will be described with reference to FIGS. 3 to 6. FIG. 3 is a representative circuit schematic of the high frequency switch circuit of the embodiment when the first high frequency signal is outputted to the antenna terminal via the transmission terminal. FIG. 4 is a representative circuit schematic of the high frequency switch circuit of the comparative sample when the first high frequency signal is outputted to the antenna terminal via the transmission terminal. FIG. 5 is a representative circuit schematic of the high frequency switch circuit of the embodiment when the second high frequency signal is outputted to the receiver terminal via the antenna terminal. FIG. 6 is a representative circuit schematic of the high frequency switch circuit of the comparative sample when the second high frequency signal is outputted to the receiver terminal via the antenna terminal.

In the high frequency switch circuit 70 of the embodiment, let us assume that as shown in FIG. 3, the control signal Ssg1 is set in the enable state, and the control signal Ssg2 is set in the disable state. In this process, the high frequency signal Shf1 (first high frequency signal) is transmitted from the terminal Ptx1 toward the terminal Pant. Because the through transistor T1 turns on, the through transistor T1 is represented as an ON-resistance Ron1; and because the shunt transistor S2 turns on, the shunt transistor S2 is represented as an ON-resistance Ron2. Meanwhile, because the through transistor T2 turns off, the through transistor T2 is represented as an OFF-capacitance Coff1; and because the shunt transistor S1 turns off, the shunt transistor S1 is represented as an OFF-capacitance Coff2.

In this case, impedance Z on the side of load is expressed with

Z=Zs×({Zr+(jZs×Tan(β1))}/{Zs+(jZr×Tan(β1))}) Equation (1),

where: Zs denotes terminal impedance; Zr denotes load impedance; and I denotes a transmission line length (a line length from the terminal Ptx1 to the through transistor T1, or a line length from the through transistor T2 to the terminal Prx1). β is equal to 2π/Δ (where Δ denotes the wavelength of the first or second high frequency signal).

In the high frequency switch circuit 70 of the embodiment, on a channel from the terminal Ptx1 to the terminal Pant, the characteristic impedances of the transmission lines TL1, TL2 are set at the same value as the terminal impedance Zs1 is. For this reason, it is learned from Equation (1) that: the impedance Z becomes equal to the load impedance Zr; and the characteristic impedances of the transmission lines are not dependent on the line lengths. Accordingly, the amount of transmission of the high frequency signal Shf1 from the terminal Ptx1 to the terminal Pant is kept at an excellent value since the amount is not influenced by the arrangement of the transmission lines TL1, TL2, and the high frequency signal Shf1 does not deteriorate.

Meanwhile, the channel from the terminal Pant to the terminal Prx1 is connected to the ground potential Vss via the shunt transistor S2.

For this reason, the load impedance Zr becomes almost equal to 0 (zero) Ω. Substituting Zr=0 into Equation (1) yields

Z≈(jZs×Tan(β1)) Equation (2),

with which the impedance Z can be expressed.

The line lengths of the transmission lines TL3, TL4 at the frequency of the high frequency signal Shf2 (second high frequency signal), which is equal to that of the high frequency signal Shf1 (first high frequency signal), are equal to λ/6 and λ/12, respectively. Since the transmission line TL3 and the transmission line TL4 are connected together in series, the two transmission lines TL3, TL4 can be represented as an aggregate transmission line whose line length is equal to λ/4.

Substituting I=λ/4 into Equation (2) allows the impedance Z to be expressed with Z≈∞ (infinity). The impedance Z of the resonance circuit 2 is also set at Z≈∞.

Consequently, inflow of a high frequency signal (fo), which is part of the high frequency signal Shf1 (first high frequency signal), from the terminal Pant into the terminal Prx1 can be reduced to a large extent. In other words, the leakage of the high frequency signal (fo) can be reduced. Accordingly, the high frequency switch circuit 70 is capable of enhancing the quality by reducing insertion loss to a large extent.

While the second harmonic (2fo) of the high frequency signal Shf2 (second high frequency signal) whose frequency is equal to that of the high frequency signal Shf1 (first high frequency signal) is generated, the characteristic impedance of the resonance circuit 2 is set to almost infinity. While the second harmonic (2fo) is generated, the two transmission lines TL3, TL4 can be represented as an aggregate transmission line whose line length is equal to λ/2. Substituting I=λ/2 into Equation (2) shows that the impedance Z become almost equal to zero.

For this reason, while the second harmonic (2fo) is generated, the high frequency switch circuit 70 is capable of reducing leakage power to a large extent.

While the third harmonic (3fo) of the high frequency signal Shf2 (second high frequency signal) whose frequency is equal to that of the high frequency signal Shf1 (first high frequency signal) is generated, the characteristic impedance of the resonance circuit 2 is set at almost zero. While the third harmonic (3fo) is generated, the two transmission lines TL3, TL4 can be represented as an aggregate transmission line whose line length is equal to λ/2. Substituting I=λ/2 into Equation (2) shows that the impedance Z become almost equal to zero.

For this reason, while the third harmonic (3fo) is generated, the high frequency switch circuit 70 is capable of reducing leakage power to a large extent.

In the high frequency switch circuit 100 of the comparative sample, let us assume that as shown in FIG. 4, the high frequency signal Shf1 (first high frequency signal) is transmitted from the terminal Ptx1 toward the terminal Pant while: the control signal Ssg1 is set in the enable state; and the control signal Ssg2 is set in the disable state. In this case, the through transistor T1, the through transistor T2, the shunt transistor S1 and the shunt transistor S2 can be represented in the same manner as are those shown in FIG. 3.

In the high frequency switch circuit 100 of the comparative sample, neither the transmission line TL3 nor the transmission line TL4 is provided between the through transistor T2 and the terminal Prx1, and no resonance circuit 2 is provided between the transmission line TL3 and the ground potential Vss. For this reason, part of the high frequency signal Shf1 (first high frequency signal) leaks to the side of the terminal Prx1 via the OFF capacitance Coff1 which is connected to the terminal Prx1 in series. Furthermore, the second and third harmonics of the high frequency signal Shf1 (first high frequency signal) leak.

In the high frequency switch circuit 70 of the embodiment, let us assume that as shown in FIG. 5, the control signal Ssg1 is set in the disable state, and the control signal Ssg2 is set in the enable state. In this process, the high frequency signal Shf2 (second high frequency signal) is transmitted from the terminal Pant toward the terminal Prx1. Because the through transistor T2 turns on, the through transistor T2 is represented as an ON-resistance Ron3; and because the shunt transistor S1 turns on, the shunt transistor S1 is represented as an ON-resistance Ron4.

Meanwhile, because the through transistor T1 turns off, the through transistor T1 is represented as an OFF-capacitance Coff3; and because the shunt transistor S2 turns off, the shunt transistor S2 is represented as an OFF-capacitance Coff4.

In this case, the impedance Z on the side of load is expressed with Equation (1). In the high frequency switch circuit 70 of the embodiment, on a channel from the terminal Pant to the terminal Prx1, the characteristic impedances of the transmission lines TL3, TL4 are set at the same value as the terminal impedance Zs2 is. For this reason, it is learned from Equation (1) that: the impedance Z becomes equal to the load impedance Zr; and the characteristic impedances of the transmission lines are not dependent on the line lengths. Accordingly, the amount of transmission of the high frequency signal Shf2 from the terminal Pant to the terminal Prx1 is kept at an excellent value since the amount is not influenced by the arrangement of the transmission lines TL3, TL4, and the high frequency signal Shf2 does not deteriorate.

Meanwhile, the channel from the terminal Pant to the terminal Prx1 is connected to the lower potential-side power supply (ground potential) Vss via the shunt transistor S1. For this reason, the load impedance Zr becomes almost equal to 0 (zero) Ω.

The line lengths of the transmission lines TL1, TL2 at the frequency of the high frequency signal Shf2 (second high frequency signal), which is equal to that of the high frequency signal Shf1 (first high frequency signal), are equal to λ/12 and λ/6, respectively. Since the transmission line TL1 and the transmission line TL2 are connected together in series, the two transmission lines TL1, TL2 can be represented as an aggregate transmission line whose line length is equal to λ/4.

Substituting I=λ/4 into Equation (2) allows the impedance Z to be expressed with Z≈∞ (infinity). The characteristic impedance of the resonance circuit 1 is also set to almost infinity.

Consequently, leak of part of the high frequency signal Shf2 from the terminal Pant to the side of the terminal Ptx1 can be reduced to a large extent. Accordingly, the high frequency switch circuit 70 is capable of enhancing the quality by reducing the insertion loss to a large extent.

While the second harmonic (2fo) of the high frequency signal Shf1 (first high frequency signal) whose frequency is equal to that of the high frequency signal Shf2 (second high frequency signal), the characteristic impedance of the resonance circuit 1 is set to almost infinity. While the second harmonic (2fo) is generated, the two transmission lines TL1, TL2 can be represented as an aggregate transmission line whose line length is equal to λ/2. Substituting I=λ/2 into Equation (2) shows that the impedance Z become almost equal to zero (Z≈0).

For this reason, while the second harmonic (2fo) is generated, the high frequency switch circuit 70 is capable of reducing leakage power to a large extent.

While the third harmonic (3fo) of the high frequency signal Shf1 (first high frequency signal) whose frequency is equal to that of the high frequency signal Shf2 (second high frequency signal), the characteristic impedance of the resonance circuit 1 is set at almost zero. While the third harmonic (3fo) is generated, the two transmission lines TL1, TL2 can be represented as an aggregate transmission line whose line length is equal to λ/2. Substituting I=λ/2 into Equation (2) shows that the impedance Z become almost equal to zero (Z≈0).

For this reason, while the third harmonic (3fo) is generated, the high frequency switch circuit 70 is capable of reducing leakage power to a large extent.

As shown in FIG. 6, in the high frequency switch circuit 100 of the comparative sample, neither the transmission line TL1 nor the transmission line TL2 is provided between the through transistor T1 and the terminal Ptx1, and no resonance circuit 1 is provided between the other end of transmission line TL1 and the ground potential Vss. For this reason, part of the high frequency signal Shf2 (second high frequency signal) leaks to the side of the terminal Ptx1 via the OFF capacitance Coff3 which is connected to the terminal Ptx1 in series. Furthermore, the second and third harmonics of the high frequency signal Shf2 (second high frequency signal) leak.

In the high frequency switch circuit 70 of the embodiment, the line lengths of the transmission lines TL1, TL4 at the frequency of the first and second high frequency signals are set equal to λ/12, respectively; and the line lengths of the transmission lines TL2, TL3 at the frequency of the first and second high frequency signals are set equal to λ/6, respectively. Nevertheless, each line length may have an error which can be represented by a predetermined value.

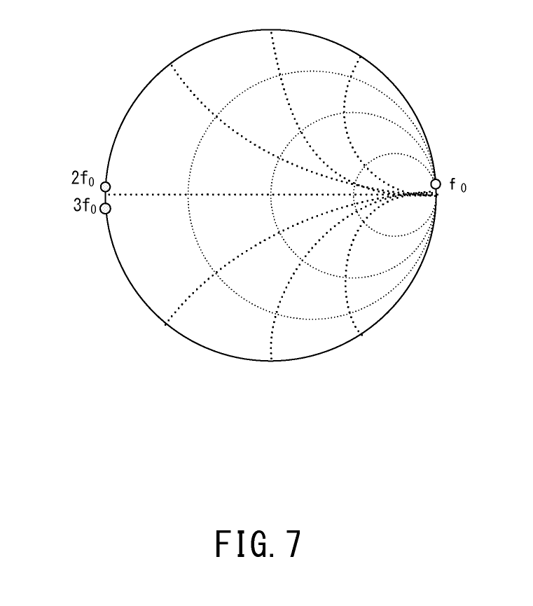

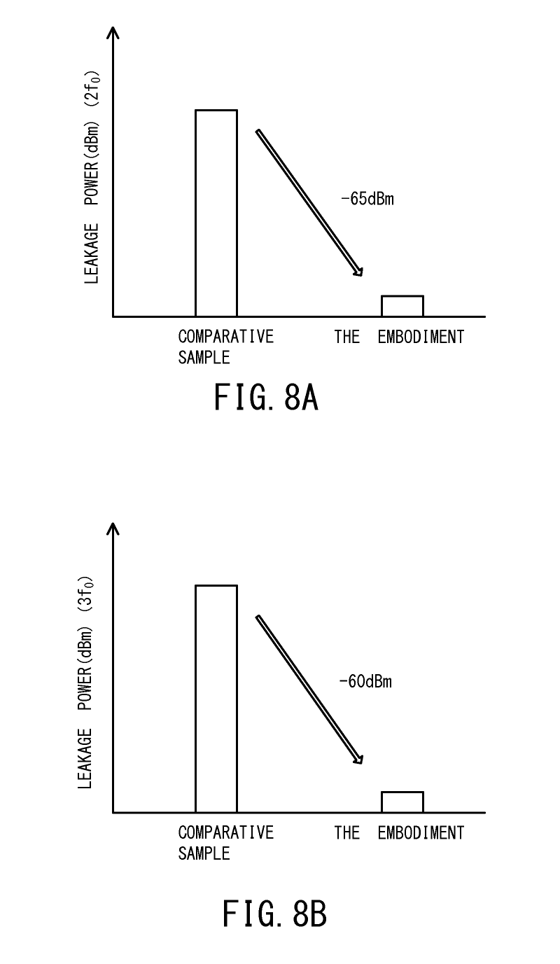

Next, characteristics of the high frequency switch circuit 70 of the embodiment and characteristics of the high frequency switch circuit 100 of the comparative sample will be described with reference to FIGS. 7, 8A and 8B. FIG. 7 is a Smith chart of the high frequency switch circuit of the embodiment. FIG. 8A is a diagram showing leakage powers while the second harmonic of the first and second high frequency signals is generated. FIG. 8B is a diagram showing leakage powers while the third harmonic of the first and second high frequency signals is generated.

FIGS. 7, 8A and 8B are characteristic diagrams explaining the high frequency switch circuits on the assumption that: the frequency of the first and second high frequency signals (fo) is at 2 GHz; the frequency of the second harmonic (2fo) of the first and second high frequency signals is at 4 GHz; and the frequency of the third harmonic (3fo) of the first and second high frequency signals is at 6 GHz.

As shown in FIG. 7, in the high frequency switch circuit 70 of the embodiment, the impedance Z at the frequency of the first and second high frequency signals (fo) is almost equal to infinity (Z≈∞). The impedance Z at the frequency of the second harmonic (2fo) of the first and second high frequency signals, and the impedance Z at the frequency of the third harmonic (3fo) of the first and second high frequency signals are almost equal to zero (Z≈0).

The high frequency switch circuit 70 of the embodiment is capable of reducing the impedance Z to almost zero (Z≈0) while the second harmonic (2fo) and the third harmonic (3fo) are generated. Accordingly, the high frequency switch circuit 70 of the embodiment is capable of reducing the leakage power to almost a measurement limit while the second harmonic (2fo) and the third harmonic (3fo) are generated.

Meanwhile, the high frequency switch circuit 100 of the comparative sample causes power leakage while the second and third harmonics are generated.

As shown in FIG. 8A, while the second harmonic (2fo) is generated, the high frequency switch circuit 70 of the embodiment is capable of reducing the leakage power to such a large extent that the leakage power in the high frequency switch circuit 70 of the embodiment is smaller than that in the high frequency switch circuit 100 of the comparative sample by 65 dBm. As shown in FIG. 8B, while the third harmonic (3fo) is generated, the high frequency switch circuit 70 of the embodiment is capable of reducing the leakage power to such a large extent that the leakage power in the high frequency switch circuit 70 of the embodiment is smaller than that in the high frequency switch circuit 100 of the comparative sample by 60 dBm.

As described above, the high frequency switch circuit of the embodiment includes the resonance circuit 1, the resonance circuit 2, the shunt transistor S1, the shunt transistor S2, the through transistor T1, the through transistor T2, the transmission line TL1, the transmission line TL2, the transmission line TL3, the transmission line TL4, the terminal Pant, the terminal Prx1, the terminal Ptx1, the terminal PVc1 and the terminal PVc2.

The transmission lines at the frequency of the first and second high frequency signals (fo) are represented as the aggregate transmission line whose line length is equal to λ/4. The transmission lines at the frequency of the second harmonic (2fo) of the first and second high frequency signals are represented as the aggregate transmission line whose line length is equal to λ/2. The transmission lines at the frequency of the third harmonic (3fo) of the first and second high frequency signals are represented as the aggregate transmission line whose line length is equal to λ/2.

For these reason, the high frequency switch circuit 70 is capable of enhancing the quality by reducing the insertion loss to the large extent, and is capable of reducing the leakage power to the large extent while the second harmonic (2fo) and the third harmonic (3fo) are generated.

In the embodiment, the line length of the transmission line TL1 is set at λ/12, the line length of the transmission line TL2 is set at λ/6, the line length of the transmission line TL3 is set at λ/6, and the line length of the transmission line TL4 is set at λ/12. It should be noted, however, that the invention is not necessary limited to the above case. The line length of the transmission line TL1 may be set at λ[n+( 1/12)], the line length of the transmission line TL2 is set at λ[n+(⅙)], the line length of the transmission line TL3 is set at λ[n+(⅙)], and the line length of the transmission line TL4 is set at λ[n+( 1/12)]. In this respect, n is zero, or an integer equal to or greater 1(one).

Furthermore, in the embodiment, for the purpose of reducing the leakage power while the second harmonic (2fo) and the third harmonic (3fo) are generated, the line lengths of the transmission lines TL1 to TL4 are set at the above values, respectively, and the resonance circuits 1, 2 are provided to the high frequency switch circuit 70. In the case where only the leakage power while the second harmonic (2fo) is generated is attempted to be reduced, neither the resonance circuit 1 nor the resonance circuit 2 is needed. The line length of the aggregate transmission line of the transmission line TL1 and the transmission line TL2 may be set equal to (m/4) times the wavelength (λ) of the first high frequency signal, while the line length of the aggregate transmission line of the transmission line TL3 and the transmission line TL4 may be set equal to (m/4) times the wavelength (λ) of the second high frequency signal. In this respect, m is an integer equal to or greater than 1 (one).

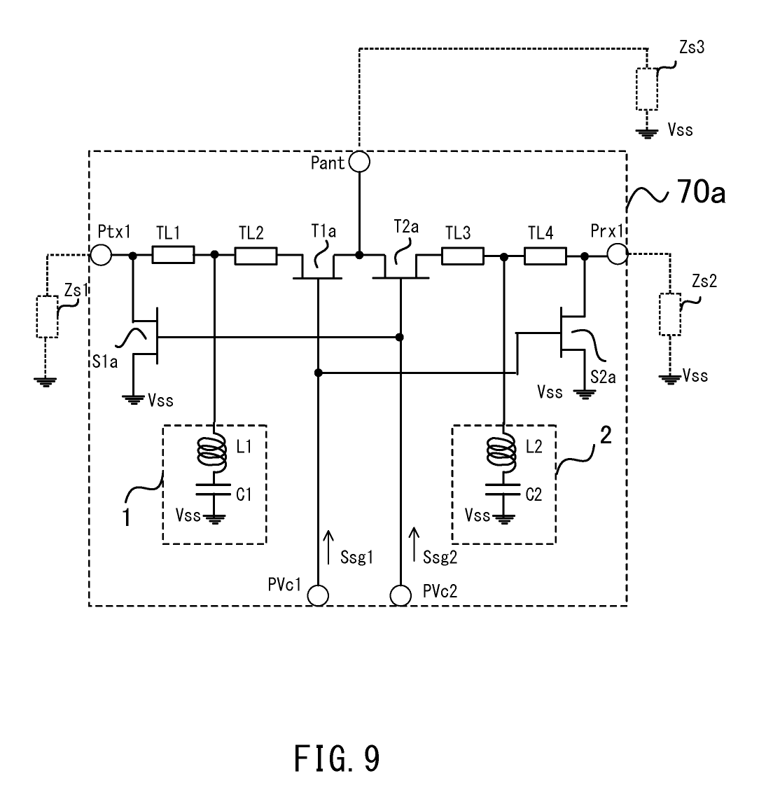

A high frequency switch circuit of a second embodiment will be described with reference to FIG. 9. FIG. 9 is a circuit diagram showing the high frequency switch circuit. The embodiment uses transistors which are different from some of those used in the first embodiment.

Hereinbelow, portions which are the same as those in the first embodiment will be denoted by the same reference signs. Descriptions for such portions will be omitted, and only the different portions will be described.

As shown in FIG. 9, a high frequency switch circuit 70a includes the resonance circuit 1, the resonance circuit 2, a shunt transistor S1a, a shunt transistor S2a, a through transistor T1a, a through transistor T2a, the transmission line TL1, the transmission line TL2, the transmission line TL3, the transmission line TL4, the terminal Pant, the terminal Prx1, the terminal Ptx1, the terminal PVc1 and the terminal PVc2.

One end of the shunt transistor S1a is connected to the terminal Ptx1. The control signal Ssg2 is inputted into the control terminal of the shunt transistor S1a. The other end of the shunt transistor S1a is connected to the ground potential Vss.

One end of the through transistor T1a is connected to the other end of the transmission line TL2. The control signal Ssg1 is inputted into the control terminal of the through transistor T1a. The other end of the through transistor T1a is connected to the terminal Pant.

One end of the through transistor T2a is connected to the terminal Pant. The control signal Ssg2 is inputted into the control terminal of the through transistor T2a. The other end of the through transistor T2a is connected to the one end of the transmission line TL3.

One end of the shunt transistor S2a is connected to the other end of the transmission line TL4 and the terminal Prx1. The control signal Ssg1 is inputted into the control terminal of the shunt transistor S2a. The other end of the shunt transistor S2a is connected to the ground potential Vss.

In the second embodiment, a PHEMT (Pseudomorphic High Electron Mobility Transistor) (R) is used for the shunt transistor S1a, the shunt transistor S2a, the through transistor T1a and the through transistor T2a. The PHEMT is a field effect transistor incorporating high-mobility two-dimensional electron gas (2DEG), which is induced by semiconductor heterojunction, as the channel instead of a conventionally-used material for pseudo lattice match. The PHEMT is capable of making the frequency become higher and noise become lower, for example, than the SOI-type MOSFET and the HEMT.

As described above, the high frequency switch circuit of the embodiment includes the resonance circuit 1, the resonance circuit 2, the shunt transistor S1a, the shunt transistor S2a, the through transistor T1a, the through transistor T2a, the transmission line TL1, the transmission line TL2, the transmission line TL3, the transmission line TL4, the terminal Pant, the terminal Prx1, the terminal Ptx1, the terminal PVc1 and the terminal PVc2.

For this reason, the high frequency switch circuit of the second embodiment exerts the same effect as the high frequency switch circuit of the first embodiment.

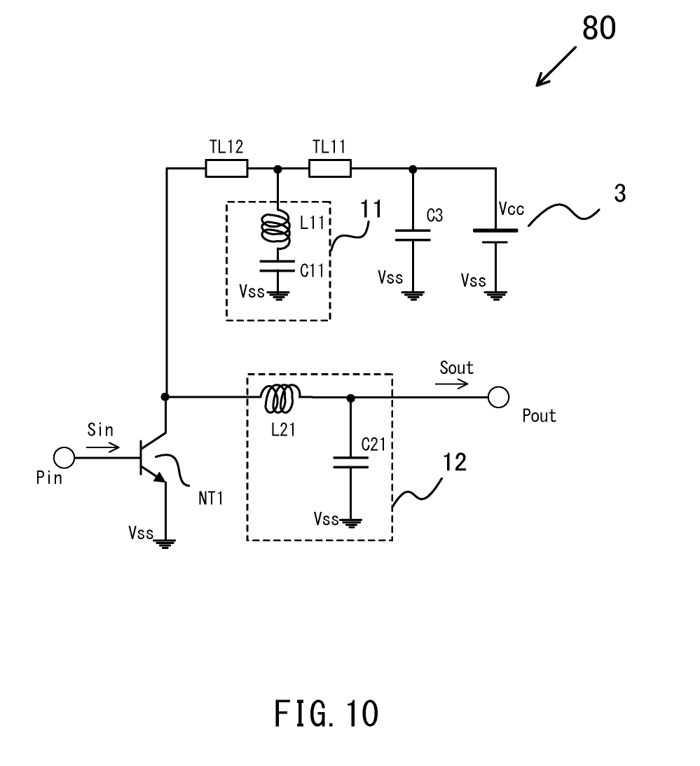

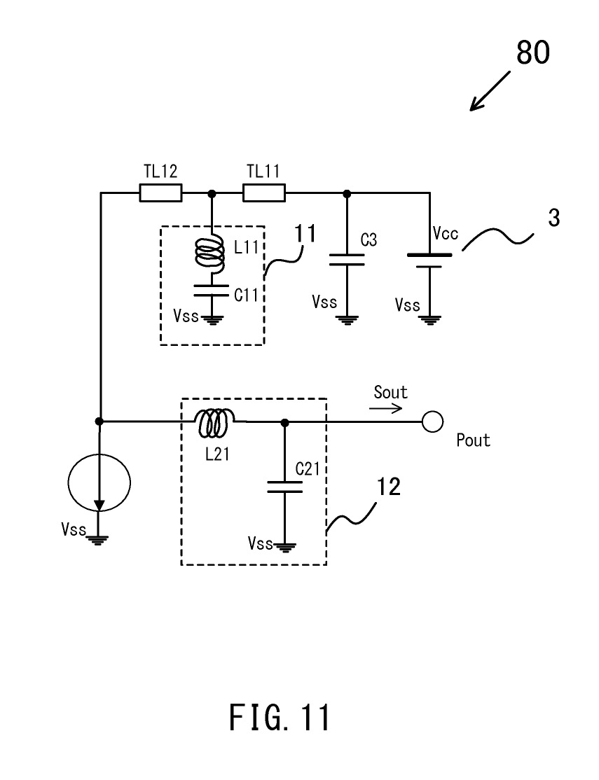

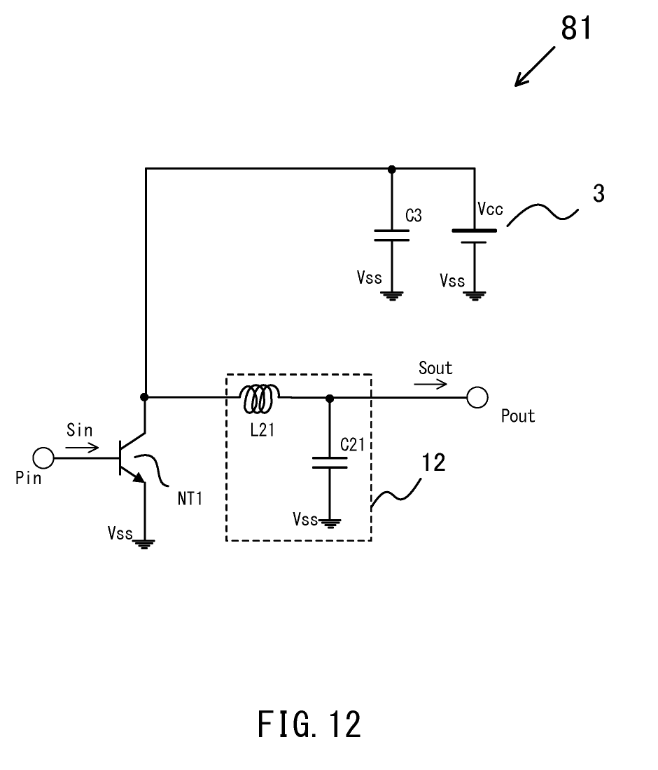

A high frequency power amplifier circuit, as a high frequency semiconductor integrated circuit of a third embodiment, will be described with reference to FIGS. 10 to 12. FIG. 10 is a circuit diagram showing the high frequency power amplifier circuit as the high frequency semiconductor integrated circuit. FIG. 11 is a representative circuit schematic of the high frequency power amplifier circuit of the embodiment. FIG. 12 is a circuit diagram showing a high frequency power amplifier circuit of a comparative sample.

The embodiment reduces leakage signal to a large extent by: providing a first transmission line and a second transmission line between one end of an NPN transistor and a power supply; and providing a first resonance circuit between a ground potential and the connection point between the first transmission line and the second transmission line.

As shown in FIG. 10, the high frequency power amplifier circuit 80, as the high frequency semiconductor integrated circuit, includes a power supply 3, a resonance circuit 11, a matching circuit 12, a capacitor C3, an NPN transistor NT1, a transmission line TL11, a transmission line TL12, an input terminal Pin and an output terminal Pout. The high frequency power amplifier circuit 80 is widely used in cellular phones, wireless infrastructure facilities, satellite communications facilities, cable television facilities, and the like. The high frequency power amplifier circuit 80 is also referred to as a high frequency power amplifier.

An input signal Sin (first high frequency signal) is inputted into the base (control terminal) of the NPN transistor NT1 via the input terminal Pin. The NPN transistor NT1 outputs an amplified signal, which is obtained by amplifying the input signal Sin, from the collector (one end). The emitter (the other end) of the NPN transistor NT1 is connected to the ground potential Vss. A HBT (Heterojunction Bipolar transistor), for example, is used as the NPN transistor NT1. Incidentally, a power HEMT (High Electron Mobility Transistor) or the like may be used instead of the NPN transistor NT1.

The matching circuit 12 is provided between the one end of the NPN transistor NT1 and the output terminal Pout. The matching circuit 12 performs impedance matching on the amplified signal. The matching circuit 12 outputs an impedance-matched output signal Sout to the output terminal Pout. The impedance at the frequency of the output signal Sout is matched to 50Ω.

The matching circuit 12 includes an inductor L21 and a capacitor C21. One end of the inductor L21 is connected to the one end of the NPN transistor NT1. The other end of the inductor L21 is connected to the output terminal Pout. One end of the capacitor C21 is connected to the other end of the inductor L21. The other end of capacitor C21 is connected to the ground potential Vss.

One end of the transmission line TL12 (first line) is connected to the one end of the NPN transistor NT1. The transmission line TL12 (first line) is set such that once a first high frequency signal (the amplified signal to be outputted from the one end of the NPN transistor NT1) to be transmitted is inputted into the transmission line TL12, a line length of the transmission line TL12 becomes equal to one sixth of the wavelength (λ) of the first high frequency signal.

One end of the transmission line TL11 (second line) is connected to the other end of the transmission line TL12. The other end of the transmission line TL11 (second line) is connected to the high potential side of the power supply 3. The transmission line TL11 (second line) is set such that once the first high frequency signal (the amplified signal to be outputted from the one end of the NPN transistor NT1) to be transmitted is inputted into the transmission line T11, a line length of the transmission line TL11 becomes equal to one twelfth of the wavelength (λ) of the first high frequency signal.

One end of the resonance circuit 11 (first resonance circuit) is connected to the other end of the transmission line TL12, and the other end of the resonance circuit 11 is connected to the ground potential Vss. The resonance circuit 11 is formed from an inductor L11 and a capacitor C11 connected together in series. Characteristic impedance of the resonance circuit 11 at a frequency equal to or less than that of the second harmonic of the first high frequency signal is set to almost infinity. Characteristic impedance of the resonance circuit 11 at a frequency of the third harmonic of the first high frequency signal is set at almost zero.

In the case shown in FIG. 10, the inductor L11 is provided on the side of the other end of the transmission line TL12, while the capacitor C11 is provided on the side of the ground potential Vss. However, the inductor L11 and the capacitor C11 may be reversely provided such that: the capacitor C11 is provided on the side of the other end of the transmission line TL12; and the inductor L11 is provided on the side of the ground potential Vss.

One end of the capacitor C3 is connected to the other end of the transmission line TL11 and the high potential side of the power supply 3. The other end of the capacitor C3 is connected to the ground potential Vss. The capacitor C3 has a relatively large capacitance which allows the capacitor C3 to short-circuit at a frequency equal to or greater than that of the first high frequency signal (fo). In a case where the first high frequency signal (fo) is at 2 Hz, for example, the capacitance of the capacitor C3 is set equal to or greater than 100 pF.

The high potential side of the power supply 3 is connected to the other end of the transmission line TL11. The low potential side of the power supply 3 is connected to the ground potential Vss. The power supply 3 supplies a power supply voltage Vcc to the one end of the NPN transistor NT1 via the transmission line TL12 and the transmission line TL11.

As shown in FIG. 11, the NPN transistor NT1 of the high frequency power amplifier circuit 80 can be represented as a current source which operates once: the power supply voltage Vcc is applied to the one end of the NPN transistor NT1; and the input signal Sin (first high frequency signal) is inputted into the base of the NPN transistor NT1.

As shown in FIG. 12, a high frequency power amplifier circuit 81 of the comparative sample includes the power supply 3, the matching circuit 12, the capacitor C3, the NPN transistor NT1, the input terminal Pin and the output terminal Pout. The high frequency power amplifier circuit 81 of the comparative sample lacks the transmission line TL11, the transmission line TL12 and the resonance circuit 11 which are included in the high frequency power amplifier circuit 80 of the embodiment. For this reason, descriptions for the configuration of the high frequency power amplifier circuit 81 of the comparative sample will be omitted.

Next, descriptions will be provided for how the high frequency power amplifier circuit 80 of the embodiment works, and how the high frequency power amplifier circuit 81 of the comparative sample works.

In the high frequency power amplifier circuit 80 of the embodiment, once the first high frequency signal (fo) is transmitted to the transmission line TL12 and the transmission line TL11 from the one end of the NPN transistor NT1, a line length of the transmission line TL12 becomes equal to one sixth of the wavelength of the first high frequency signal, and a line length of the transmission line TL11 becomes equal to one twelfth of the wavelength of the first high frequency signal. Since the transmission line TL12 and the transmission line TL11 are connected together in series, the two transmission lines TL11, TL12 can be represented as an aggregate transmission line whose line length is equal to λ/4.

Like in the first embodiment, substituting I=λ/4 into Equation (2) allows the impedance Z to be expressed with Z≈∞ (infinity). The characteristic impedance of the resonance circuit 11 is also set at Z≈∞.

For this reason, the leak of the first high frequency signal (the amplified signal to be outputted from the one end of the NPN transistor NT1) in the transmission line TL12, the transmission line TL11 and the transmission line TL12 can be reduced to a large extent.

While the second harmonic (2fo) of the first high frequency signal (fo) is generated, the characteristic impedance of the resonance circuit 11 is set to almost infinity. While the second harmonic (2fo) is generated, the two transmission lines TL11, TL12 can be represented as an aggregate transmission line whose line length is equal to λ/2. Like in the first embodiment, substituting I=λ/2 into Equation (2) shows that the impedance Z becomes almost equal to zero.

For this reason, while the second harmonic (2fo) is generated, the high frequency power amplifier circuit 80 is capable of reducing leakage power to a large extent.

While the third harmonic (3fo) of the first high frequency signal (fo) is generated, the characteristic impedance of the resonance circuit 11 is set at almost zero. While the third harmonic (3fo) is generated, the two transmission lines TL11, TL12 can be represented as an aggregate transmission line whose line length is equal to λ/2. Like in the first embodiment, substituting I=λ/2 into Equation (2) shows that the impedance Z becomes almost equal to zero.

For this reason, while the third harmonic (3fo) is generated, the high frequency power amplifier circuit 80 is capable of reducing leakage power to a large extent.

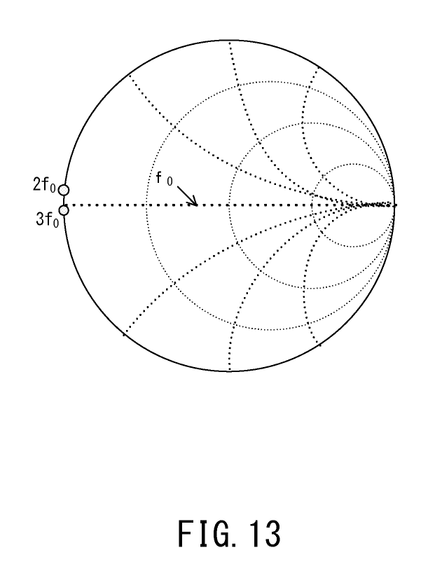

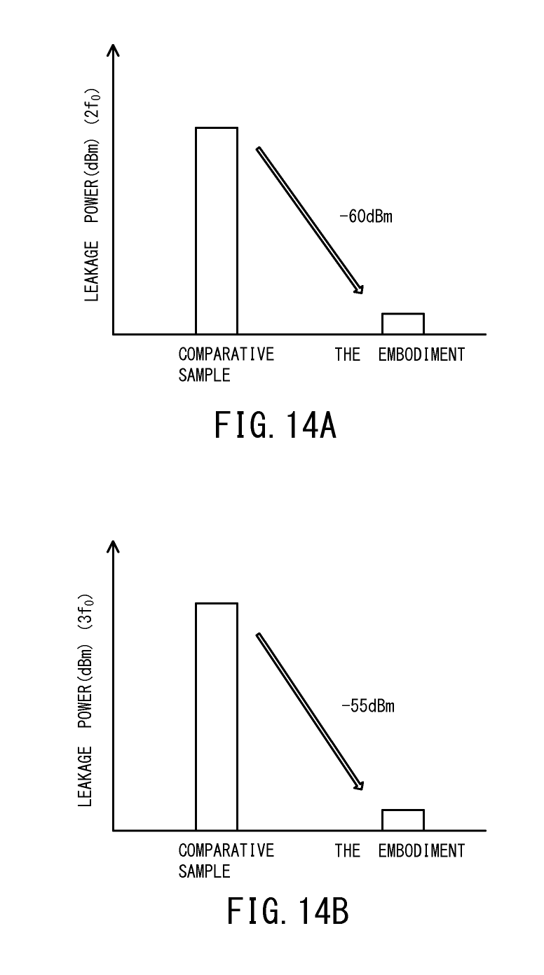

Next, characteristics of the high frequency power amplifier circuit 80 of the embodiment and characteristics of the high frequency power amplifier circuit 81 of the comparative sample will be described with reference to FIGS. 13, 14A and 14B. FIG. 13 is a Smith chart of the high frequency power amplifier circuit of the embodiment. FIG. 14A is a diagram showing leakage powers while the second harmonic of the high frequency signal is generated. FIG. 14B is a diagram showing leakage powers while the third harmonic of the high frequency signal is generated.

FIGS. 13, 14A and 14B are characteristic diagrams explaining the high frequency power amplifier circuits on the assumption that: the frequency of the first high frequency signal (fo) is at 2 GHz; the frequency of the second harmonic (2fo) of the first high frequency signal is at 4 GHz; and the frequency of the third harmonic (3fo) of the first high frequency signal is at 6 GHz.

As shown in FIG. 13, in the high frequency power amplifier circuit 80 of the embodiment, the impedance Z at the frequency of the first high frequency signal (fo) is almost equal to infinity (Z≈∞). The impedance Z at the frequency of the second harmonic (2fo) of the first high frequency signal, and the impedance Z at the frequency of the third harmonic (3fo) of the first high frequency signal are almost equal to zero (Z≈0).

The high frequency power amplifier circuit 80 of the embodiment is capable of reducing the impedance Z to almost zero (Z≈0) while the second harmonic (2fo) and the third harmonic (3fo) are generated. Accordingly, the high frequency power amplifier circuit 80 of the embodiment is capable of reducing the leakage power to almost a measurement limit while the second harmonic (2fo) and the third harmonic (3fo) are generated.

Meanwhile, the high frequency power amplifier circuit 81 of the comparative sample causes power leakage while the second and third harmonics are generated.

As shown in FIG. 14A, while the second harmonic (2fo) is generated, the high frequency power amplifier circuit 80 of the embodiment is capable of reducing the leakage power to such a large extent that the leakage power in the high frequency power amplifier circuit 80 of the embodiment is smaller than that in the high frequency power amplifier circuit 81 of the comparative sample by 60 dBm. As shown in FIG. 14B, while the third harmonic (3fo) is generated, the high frequency power amplifier circuit 80 of the embodiment is capable of reducing the leakage power to such a large extent that the leakage power in the high frequency power amplifier circuit 80 of the embodiment is smaller than that in the high frequency power amplifier circuit 81 of the comparative sample by 55 dBm.

As described above, the high frequency power amplifier circuit 80 of the embodiment includes the power supply 3, the resonance circuit 11, the matching circuit 12, the capacitor C3, the NPN transistor NT1, the transmission line TL11, the transmission line TL12, the input terminal Pin and the output terminal Pout. The transmission lines at the frequency of the first high frequency signal (fo) are represented as the aggregate transmission line whose line length is equal to λ/4. The transmission lines at the frequency of the second harmonic (2fo) of the first high frequency signal are represented as the aggregate transmission line whose line length is equal to λ/2. The transmission lines at the frequency of the third harmonic (3fo) of the first high frequency signal are represented as the aggregate transmission line whose line length is equal to λ/2.

For these reason, the high frequency power amplifier circuit 80 is capable of reducing the leakage power to the large extent while the second harmonic (2fo) and the third harmonic (3fo) are generated.

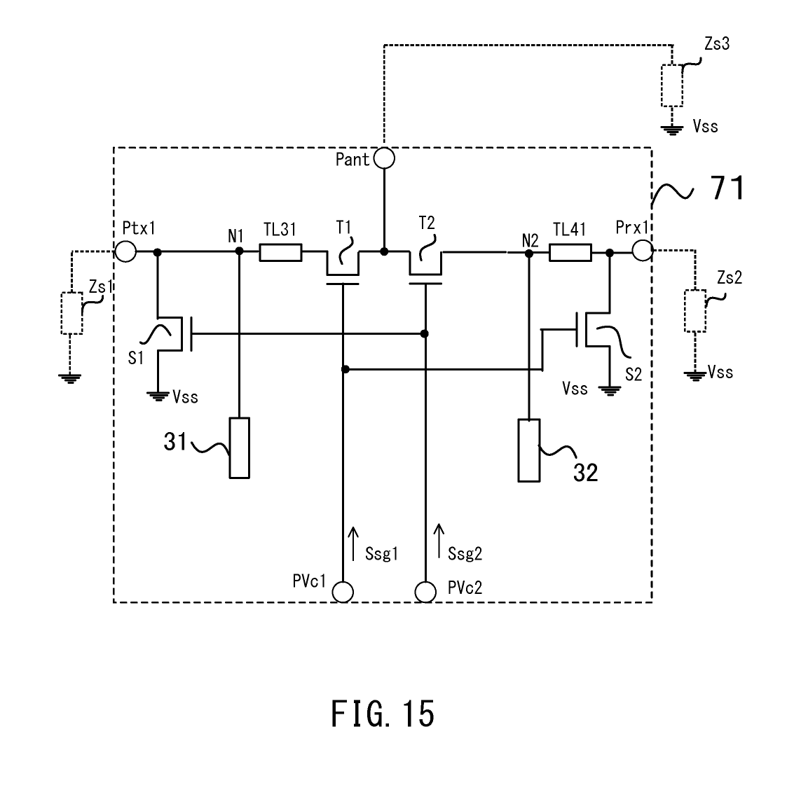

A high frequency switch circuit of a fourth embodiment will be described with reference to FIG. 15. FIG. 15 is a circuit diagram showing the high frequency switch circuit. The high frequency switch circuit of the embodiment includes the open stubs. Using open stubs, the high frequency switch circuit of the embodiment reduces leakage signal to a large extent while the third harmonic (3fo) of the first and second high frequency signals is generated.

Hereinbelow, portions which are the same as those in the first embodiment will be denoted by the same reference signs. Descriptions for such portions will be omitted, and only the different portions will be described.

As shown in FIG. 15, a high frequency switch circuit 71, as the high frequency semiconductor integrated circuit, includes an open stub 31, an open stub 32, the shunt transistor S1, the shunt transistor S2, the through transistor T1, the through transistor T2, a transmission line TL31, a transmission line TL41, the terminal Pant, the terminal Prx1, the terminal Ptx1, the terminal PVc1 and the terminal PVc2.

One end of the open stub 31 (first open stub) is connected to a node N1 (between the terminal Ptx1 and the transmission line TL31). The other end of the open stub 31 is left open-circuit. The open stub 31 is provided corresponding to the third harmonic (3fo) of the first high frequency signal.

To put it concretely, a line length of the open stub 31 is set at [n+( 1/12)] times the wavelength of the first high frequency signal, where n is an integer equal to or greater than 1 (one). When the third harmonic (3fo) of the first high frequency signal is generated, the open stub 31 short-circuits the node N1. While the open stub 31 receives the first high frequency signal, the open stub 31 keeps the node N1 open, and thereby allows the first high frequency signal to pass through. As a result, the high frequency switch circuit 71 is capable of reducing leakage signal while the third harmonic (3fo) of the first high frequency signal is generated.

One end of the open stub 32 (second open stub) is connected to a node N2 (between the terminal Prx1 and the transmission line TL41). The other end of the open stub 32 is left open-circuit. The open stub 32 is provided corresponding to the third harmonic (3fo) of the second high frequency signal.

To put it concretely, a line length of the open stub 32 is set at [n+( 1/12)] times the wavelength of the second high frequency signal, where n is an integer equal to or greater than 1 (one). When the third harmonic (3fo) of the second high frequency signal is generated, the open stub 32 short-circuits the node N2. While the open stub 32 receives the second high frequency signal, the open stub 32 keeps the node N2 open, and thereby allows the second high frequency signal to pass through. As a result, the high frequency switch circuit 71 is capable of reducing leakage signal while the third harmonic (3fo) of the second high frequency signal is generated.

A coplanar strip line, a microstrip line or the like, for example, is used for the open stub 31 and the open stub 32.

One end of the transmission line TL31 (first line) is connected to the node N1 (one end of the open stub 31). The other end of the transmission line TL31 is connected to one end of the through transistor T1. Characteristic impedance of the transmission line TL31 is set at the same value as the characteristic impedance Zs1 is. The transmission line TL31 is set such that once the first high frequency signal to be transmitted is inputted into the transmission line TL31, a line length of the transmission line TL31 becomes equal to (m/4) times the wavelength (λ) of the first high frequency signal, where m is an integer equal to or greater than 1 (one).

One end of the transmission line TL41 (second line) is connected to the node N2 (one end of the open stub 32). The other end of the transmission line TL41 is connected to the terminal Prx1. Characteristic impedance of the transmission line TL41 is set at the same value as the characteristic impedance Zs2 is. The transmission line TL41 is set such that once the second high frequency signal to be transmitted is inputted into the transmission line TL41, a line length of the transmission line TL41 becomes equal to (m/4) times the wavelength (λ) of the second high frequency signal, where m is an integer equal to or greater than 1 (one).

As described above, the high frequency switch circuit 71 of the embodiment includes: the open stub 31 whose length is set at [n+( 1/12)] times the wavelength of the first high frequency signal; and the open stub 32 whose length is set at [n+( 1/12)] times the wavelength of the second high frequency signal. The high frequency switch circuit 71 of the embodiment further includes: the transmission line TL31 whose line length is set at (m/4) times the wavelength (λ) of the first high frequency signal; and the transmission line TL41 whose line length is set at (m/4) times the wavelength (λ) of the second high frequency signal.

For these reasons, the high frequency switch circuit 71 is capable of enhancing the quality by reducing insertion loss to a large extent, and is capable of reducing the leakage power to the large extent while the second harmonic (2fo) and the third harmonic (3fo) are generated.

Although the embodiments set the frequency of the high frequency signals (fo) at 2 GHz, the frequency of the high frequency signals (fo) is not necessarily limited to 2 GHz. The high frequency signals (fo) is also applicable to various high frequency signals whose frequencies are at 2.5 GHz, 5 GHz, 5.7 GHz and the like. In such cases, the line lengths of the transmission lines and the open stubs need to be selected in accordance with the wavelength of the high frequency signals.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A high frequency semiconductor integrated circuit comprising:
a first line including one end connected to a first terminal, and a length of the first line configured to be equal to [n+( 1/12)] times a wavelength of a first high frequency signal when the first high frequency signal is transmitted through the first line, where n is zero, or an integer equal to or greater than one;
a first resonance circuit including one end connected to the other end of the first line and the other end connected to a ground potential;
a second line including one end connected to the other end of the first line, and a length of the second line configured to be equal to [n+(⅙)] times the wavelength of the first high frequency signal when the first high frequency signal is transmitted through the second line;
a first transistor including a control terminal to receive a first control signal, one end connected to the other end of the second line, and the other end connected to a second terminal;
a second transistor including a control terminal to receive a second control signal and one end connected to the second terminal;
a third line including one end connected to the other end of the second transistor, and a length of the third line configured to be equal to [n+(⅙)] times a wavelength of a second high frequency signal when the second high frequency signal is transmitted through the third line;
a second resonance circuit including one end connected to the other end of the third line and the other end connected to the ground potential; and
a fourth line including one end connected to the other end of the third line and the other end connected to a third terminal, and a length of the fourth line configured to be equal to [n+( 1/12)] times the wavelength of the second high frequency signal when the second high frequency signal is transmitted through the fourth line.

2. The high frequency semiconductor integrated circuit according to claim 1, wherein
characteristic impedance of the first resonance circuit at a frequency equal to or less than that of a second harmonic of the first high frequency signal is set to almost infinity,
characteristic impedance of the first resonance circuit at a frequency of a third harmonic of the first high frequency signal is set to almost zero,
characteristic impedance of the second resonance circuit at a frequency equal to or less than that of a second harmonic of the second high frequency signal is set to almost infinity, and
characteristic impedance of the second resonance circuit at a frequency of a third harmonic of the second high frequency signal is set at almost zero.

3. The high frequency semiconductor integrated circuit according to claim 1, wherein
the first and second resonance circuits are each formed from an inductor and a capacitor connected together in series.

4. The high frequency semiconductor integrated circuit according to claim 1, further comprising:
a third transistor including a control terminal to receive the second control signal, one end connected to the first terminal, and the other end connected to the ground potential; and
a fourth transistor including a control terminal to receive the first control signal, one end connected to the other end of the fourth line, and the other end connected to the ground potential.

5. The high frequency semiconductor integrated circuit according to claim 4, wherein
the first to fourth transistors are formed from one of an SOI-type N-channel MOSFET and a PHEMT (Pseudomorphic High Electron Mobility Transistor).

6. The high frequency semiconductor integrated circuit according to claim 4, wherein
the high frequency semiconductor integrated circuit is an SPDT (Single Pole Double Throw) switch.

7. The high frequency semiconductor integrated circuit according to claim 1, wherein
the first to fourth lines are one of a microstrip line and a coplanar strip line.

8. A high frequency semiconductor integrated circuit comprising:
a first open stub including one end connected to a first terminal and the other end left open-circuit, and a length of the first open stub being set at [n+( 1/12)] times a wavelength of a first high frequency signal, where n is zero, or an integer equal to or greater than one;
a first line including one end connected to the one end of the first open stub, and a length of the first line configured to be equal to (m/4) times the wavelength of the first high frequency signal when the first high frequency signal is transmitted through the first line, where m is an integer equal to or greater than one;
a first transistor including a control terminal to receive a first control signal, one end connected to the other end of the first line, and the other end connected to a second terminal;
a second transistor including a control terminal to receive a second control signal and one end connected to the second terminal;
a second open stub including one end connected to the other end of the second transistor and the other end left open-circuit, and a length of the second open stub being set at [n+( 1/12)] times a wavelength of a second high frequency signal; and
a second line including one end connected to the one end of the second open stub and the other end connected to a third terminal, and a length of the second line configured to be equal to (m/4) times the wavelength of a second high frequency signal when the second high frequency signal is transmitted through the second line.

9. The high frequency semiconductor integrated circuit according to claim 8, wherein
the first open stub short-circuits the one end of the first line at a frequency of a third harmonic of the first high frequency signal, and
the second open stub short-circuits the one end of the second line at a frequency of a third harmonic of the second high frequency signal.

10. The high frequency semiconductor integrated circuit according to claim 8, wherein
the first and second open stubs are formed from one of a microstrip line and a coplanar strip line.

11. The high frequency semiconductor integrated circuit according to claim 8, further comprising:
a third transistor including a control terminal to receive the second control signal, one end connected to the first terminal, and the other end set at a ground potential; and
a fourth transistor including a control terminal to receive the first control signal, one end connected to the other end of the second line, and the other end set at the ground potential.

12. A high frequency semiconductor integrated circuit comprising:
a first transistor including a control terminal to receive a first high frequency signal, the first transistor amplifying the first high frequency signal, the first transistor outputting an amplified signal from one end of the first transistor, the first transistor including the other end connected to a ground potential;
a first line including one end connected to the one end of the first transistor, and a length of the first line configured to be equal to [n+(⅙)] times a wavelength of the amplified signal when the amplified signal is transmitted through the first line, where n is zero, or an integer equal to or greater than one;
a first resonance circuit including one end connected to the other end of the first line and the other end connected to the ground potential; and
a second line including one end connected to the other end of the first line and the other end connected to a power supply, and a length of the second line configured to be equal to [n+( 1/12)] times the wavelength of the amplified signal when the amplified signal is transmitted through the second line.

13. The high frequency semiconductor integrated circuit according to claim 12, wherein
characteristic impedance of the first resonance circuit at a frequency equal to or less than that of a second harmonic of the amplified signal is set to almost infinity, and
characteristic impedance of the first resonance circuit at a frequency of a third harmonic of the first high frequency signal is set to almost zero.

14. The high frequency semiconductor integrated circuit according to claim 12, wherein
the first resonance circuit is formed from an inductor and a capacitor which are connected together in series.

15. The high frequency semiconductor integrated circuit according to claim 12, further comprising a matching circuit provided between the one end of the first transistor and an output terminal.

16. The high frequency semiconductor integrated circuit according to claim 12, wherein
the high frequency semiconductor integrated circuit is a high frequency power amplifier circuit.
